(19) United States
(12) Patent Application Publication
(10) Pub. No.: US 2007/0204903 A1
(43) Pub. Date: Sep. 6, 2007

(54) Titanium Dioxide Particle, Photovoltaic Device With The Same And Manufacturing Method Of The Same

(76) Inventors: Satoshi Uchida, Miyagi (JP); Yoshitaka Sanehira, Miyagi (JP); Paul Brandl, Mie (JP); Mitsuru Ochiai, Tokyo (JP); Kazuhisa Konno, Mie (JP); Shigeru Suzuki, Mie (JP)

Correspondence Address: REED SMITH, LLP;ATTN: PATENT RECORDS DEPARTMENT, 599 LEXINGTON AVENUE, 29TH FLOOR, NEW YORK, NY, 10022-7650, US

(21) Appl. No.: 10/599,019

(22) PCT Filed: Mar. 4, 2005
(86) PCT No.: PCT/JP05/03712

§ 371 Date: Sep. 18, 2006

(30) Foreign Application Priority Data
Mar. 17, 2004 (JP) 2004-075641

(51) Int. Cl. H01L 31/00

(52) U.S. Cl. 136/263

(57) ABSTRACT

An inventive titanium dioxide particle has 70 to 95 wt % crystalline anatase, a BET specific surface area of 65 to 120 m2/g, and an oil absorption being 70 to 90 ml/100 g measured by the method according to JIS K5101, which particle exhibits uniformity, excellent preservability and dispersibility in an acidic aqueous solution. There is disclosed a photovoltaic device 10 which comprises a light-transmittable base material 11, and a porous film 21b formed on the base material 11, in which a dye is absorbed, and the porous film 21b having the dye absorbed thereon contains the inventive titanium dioxide particle.

### BACKGROUND OF THE INVENTION

1. Field of the Invention

The present invention relates to a titanium dioxide particle suitable for dispersing in an electrically-conductive film of a photovoltaic device, a photovoltaic device using the titanium dioxide particle, a method for manufacturing the titanium dioxide particle, and a dye-sensitized solar cell using the photovoltaic device.

2. Description of the Conventional Art

A conventional method for manufacturing a titanium dioxide fine particle is a liquid process, where niobium or tantalum is added to the titanium dioxide particle as a dopant, as disclosed in Japanese Patent Laid Open No. 2003-252624. When the titanium dioxide fine particle is manufactured by hydrolysis, a titanium dioxide precursor is mixed with water in a liquid vessel, heated, and post-treated. The niobium or tantalum is added in the mixing process or the heating process. More particularly, first, the dopant is added by the action of niobium or tantalum compound at the time of the hydrolysis of titanium alkoxide. As the niobium or tantalum compound, niobium or tantalum alkoxide is used. Further, an amine is used as a hydrolysis catalyst for the titanium alkoxide. Next, a mixture containing one or both of the titanium dioxide precursor and a complex formed with the titanium dioxide precursor and ligands and water is heated at from 150 to 300° C. in a pressure vessel. As the titanium dioxide precursor, a halogenoid titanium or an orthotitanate ester is used. When the titanium dioxide fine particle manufactured by this method is used in an electrically-conductive film of a photovoltaic device, the short circuit current is increased and a photovoltaic device having excellent photon-to-electron conversion efficiency can be obtained.

Another conventional method for manufacturing a titanium dioxide ultrafine particle containing low chlorine and low rutile is a vapor phase method as disclosed in WO 03/074426 (Claim 11, 17, 18).

In this method, a gas containing titanium tetrachloride and an oxidizing gas are introduced into a reaction vessel at from 800 to 1100° C. to react these gases, and chlorine is removed from the generated titanium dioxide by, for example, a dry dechlorinating method.

However, in the conventional method for manufacturing the titanium dioxide fine particle by the liquid process, disclosed in Japanese Patent Laid Open No. 2003-252624, the fine particle must be always dispersed in a liquid in order to inhibit agglomeration because the fine particle manufactured by the alkoxide method is nano size. As a result, there are problems, such as, difficulty in controlling the solid-liquid ratio or a liquid property, such as pH, etc.

Moreover, in the conventional method for manufacturing the titanium dioxide ultrafine particle containing low chlorine and low rutile by the vapor phase method, disclosed in WO 03/074426, there is the problem of difficulty in handling the removed chlorine.

### SUMMARY OF THE INVENTION

An object of the present invention is to provide the titanium dioxide particle and a manufacturing method of the same, wherein the primary particle size is uniform, agglomeration does not occur even if the particle is not dispersed in a dispersion liquid, preservability is excellent, chlorine is not generated, and dispersibility in an acidic aqueous solution is excellent.

Another object of the present invention is to provide a photovoltaic device and a dye-sentitized solar cell having high short circuit current density and photon-to-electron conversion efficiency by using the titanium dioxide particle of the present invention.

The invention according to Claim 1 is a titanium dioxide particle having 70 to 95 wt % crystalline anatase, a BET specific surface area of 65 to 120 m²/g, and oil absorption of 70 to 90 ml/100 g measured by the method according to JIS K5101.

The titanium dioxide particle according to Claim 1 has a uniform primary particle size, does not agglomerate, and the dispersibility in an acidic aqueous solution is excellent.

The invention according to Claim 5 is an improved photovoltaic device comprising a light-transmittable base material 11 and a porous film 21b formed on the base material 11 and a dye 21d absorbed on the film as shown in FIG. 1.

The characteristic feature of this photovoltaic device is that the porous film 21b having the dye 21d absorbed thereon contains the titanium dioxide particle 21c having 70 to 95 wt % crystalline anatase, a BET specific surface area of 65 to 120 m²/g, and an oil absorption of 70 to 90 ml/100 g measured by the method according to JIS K5101.

In the photovoltaic device according to Claim 5, since the specific surface area per unit volume of the porous film 21b is increased, the amount of the absorbed dye is increased, and the short circuit current density of a dye-sentitized solar cell 80 using this photovoltaic device 10 becomes high, and the photon-to-electron conversion efficiency also becomes high.

The invention according to Claim 13 is based on a vapor phase method which is different from that of the the conventional vapor phase method described hereinabove and is an improved manufacturing method to form a titanium dioxide particle by flame-hydrolyzing titanium tetrachloride in a hydrogen burning flame.

The characteristic feature of this manufacturing method is that the theoretical burning temperature of the flame is set within the range from 400 to 700° C.

When the titanium dioxide particle is manufactured by this method according to Claim 13, it is possible to obtain the titanium dioxide particle of Claim 1, where the primary particle size is uniform, agglomeration does not occur, and the dispersibility in an acidic aqueous solution is excellent.

The invention according to Claims 15 to 20 is a dye-sensitized solar cell using the photovoltaic device according to Claims 5 to 12, as shown in FIG. 1.

As for the dye-sensitized solar cell according to Claims 15 to 20, since the specific surface area per unit volume of the porous film 21b is increased, the amount of the absorbed dye is increased, the short circuit current density becomes high, and the photon-to-electron conversion efficiency also becomes high.

As mentioned above, according to the present invention, since the titanium dioxide particle has 70 to 95 wt % crystalline anatase, a BET specific surface area of 65 to 120 m²/g, and the oil absorption is 70 to 90 ml/100 g measured by the method according to JIS K5101, the primary particle size is uniform, agglomeration does not occur, and the dispersibility in an acidic aqueous solution is excellent. So, this titanium dioxide particle is suitable for using in an electrode of the dye-sentitized solar cell.

Moreover, when the dye-absorbed porous film is formed on the light-transmittable base material of the photovoltaic device and this dye-absorbed porous film contains the titanium dioxide particle, the specific surface area per unit volume of the porous film is increased. As a result, the amount of the absorbed dye is increased, the short circuit current density of the dye-sentitized solar cell using this photovoltaic device becomes high, and the photon-to-electron conversion efficiency becomes also high.

Moreover, in the manufacture of the titanium dioxide particle by flame-hydrolyzing titanium tetrachloride in a hydrogen burning flame, when the theoretical burning temperature of the flame is set within the range from 400 to 700° C., it is possible to obtain a titanium dioxide particle having a purity of 99.5% or more, a uniform primary particle size, agglomeration does not occur even when the particle is not dispersed in the dispersion liquid, chlorine is not generated, and the dispersibility in the acidic aqueous solution is excellent.

Furthermore, in the dye-sensitized solar cell using this photovoltaic device, since the specific surface area per the unit volume of the porous film is increased, the amount of the absorbed dye is increased, the short circuit current density becomes high, and the photon-to-electron conversion efficiency also becomes high.

### BRIEF DESCRIPTION OF DRAWINGS

FIG. 1 is a sectional view of a dye-sentitized solar cell using a photovoltaic device containing a titanium dioxide particle of the preferred embodiment of the present invention

FIG. 2 is a diagram showing a process for manufacturing a titanium dioxide particle by flame-hydrolyzing high purity titanium tetrachloride

FIG. 3 is a graph showing the particle size distribution of powders comprising titanium dioxide particles of Example 2 and Comparison example 1

FIG. 4 is a graph showing I-V curve characteristic of the dye-sentitized solar cells of Example 3 and Comparison example 2

### DETAILED DESCRIPTION OF THE INVENTION

The titanium dioxide particle of the preferred embodiment (a titanium (TiO₂) particle) has a crystalline anatase content of 70 to 95 wt %, preferably 75 to 90 wt %, a BET specific surface area of 65 to 120 m²/g, preferably 70 to 100 m²/g, and an oil absorption of 70 to 90 ml/100 g, preferably 70 to 85 ml/100 g, as measured by the method according to JIS K5101. The reason why the BET specific surface area of the titanium dioxide particle is limited within the range from 65 to 120 m²/g is that the particle size of the titanium dioxide particle may be increased when the specific surface area is less than 65 m²/g, and the productivity of the titanium dioxide is remarkably decreased when the specific surface area is more than 120 m²/g. The reason why the oil absorption is limited within the range from 70 to 90 ml/100 g is that the viscosity of a paste prepared by using an acidic aqueous solution, in which the titanium dioxide is dispersed (hereinafter, this paste is referred to as an acidic aqueous paste), becomes too low when the oil absorption is less than 70 ml/100 g, and the viscosity of the acidic aqueous paste becomes too high when the oil absorption is more than 90 ml/100 g.

The titanium dioxide particle of the invention is prepared in the following manner:

Titanium tetrachloride liquid having high purity is heated and vaporized, and the vaporized titanium tetrachloride liquid is mixed with hydrogen and air to prepare a raw material gas. The raw material gas is flame-hydrolyzed in a flame, in which hydrogen is burned, to manufacture the titanium dioxide particle. In addition, the theoretical burning temperature of the flame is set within the range from 400 to 700° C., preferably from 450 to 600° C. The reason why the theoretical burning temperature of the flame is set within the range from 400 to 700° C. is that the productivity of the titanium dioxide may be remarkably decreased when the temperature is less than 400° C., and the particle size of the manufactured titanium dioxide particle may be increased when the temperature is more than 700° C.

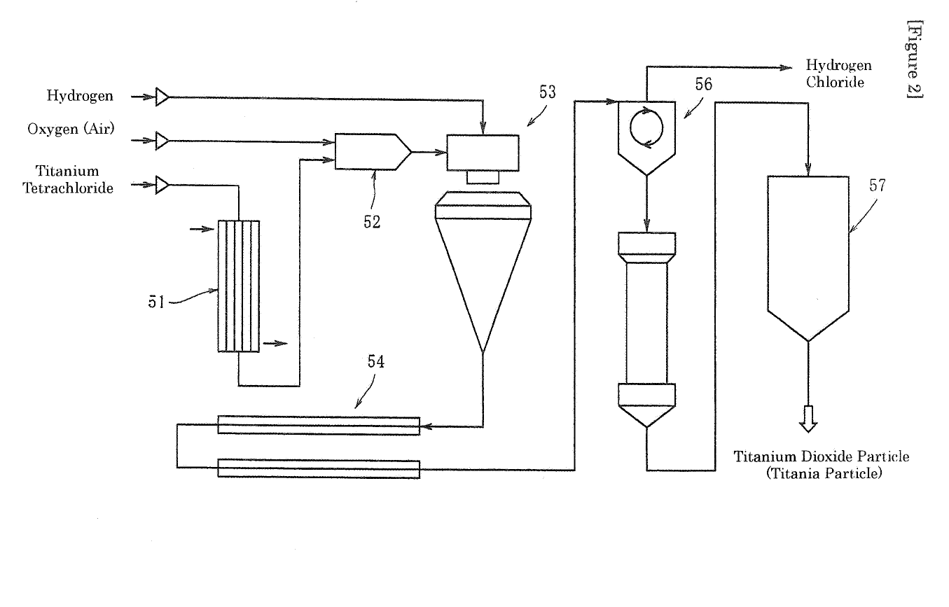

More specifically, and referring to FIG. 2, the titanium tetrachloride is first vaporized with an evaporator 51 to be fed to a mixer 52, and the vaporized titanium tetrachloride is mixed with oxygen (air) in mixer 52. Next, the mixed gas is fed to a burner 53 together with hydrogen to be burned. That is, the titanium dioxide particle (the titania particle) and a by-product (hydrogen chloride) are generated by flame-hydrolyzing the titanium tetrachloride with burner 53. Then, the titanium dioxide particle and the by-product are cooled in a cooling zone 54, and hydrogen chloride, being the by-product, is removed by a hydrogen chloride separator 56. The dechlorinated titanium dioxide particle is stored in a storage silo 57. In addition, the particle size of the generated titanium dioxide particle can be controlled by changing the conditions of flame-hydrolysis, for example, the feeding amount of the titanium tetrachloride, oxygen (air), or hydrogen.

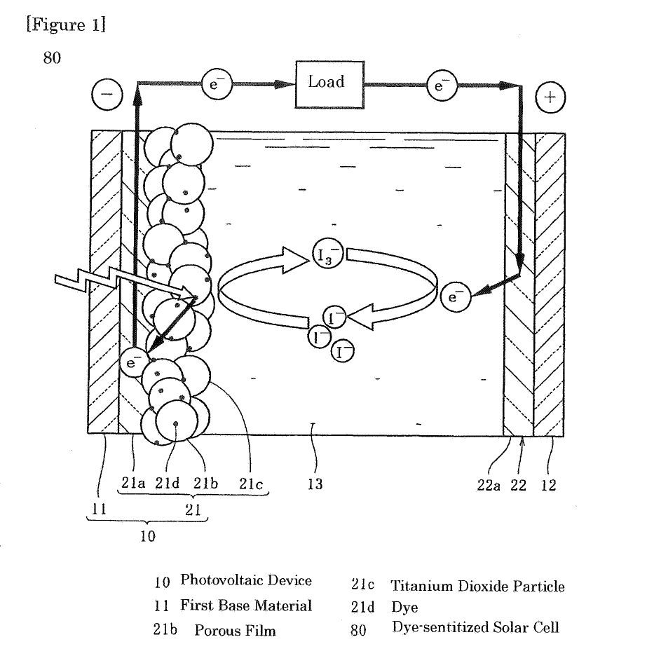

Referring to FIG. 1, the method for manufacturing photovoltaic device 10 using the titanium dioxide particle is as follows:

A first electrically-conductive film 21a is formed on a first base material 11″. Next, the acidic aqueous paste is coated on the first electrically-conductive film 21a and dried. This first electrically-conductive film 21a is formed on one side, both sides, or the entire surface of the first base material 11 by a vapor deposition method, a sputtering method, an ion plating method, hydrolysis or the like. As the first base material 11, a light-transmittable glass plate or a light-transmittable and flexible plastic film can be preferably used. As the first electrically-conductive film 21a, a film in which fluorine is doped in tin oxide (FTO) or a film in which a small amount of tin oxide is mixed with indium oxide (ITO film) can be preferably used. It is preferable that the surface resistivity of the first electrically-conductive film 21a is 5 to 15 Ω/□.

Moreover, the acidic aqueous paste is prepared by the following processes. First, the titanium dioxide particle manufactured by the above-mentioned flame-hydrolysis is mixed with an acidic aqueous solution of nitric acids hydrochloric acid, sulfuric acid or the like to prepare the acidic aqueous solution in which the titanium dioxide particle is dispersed. The pH of this acidic aqueous solution is preferably 3 or less. The reason why the pH of the acidic aqueous solution is 3 or less is that an interface potential of the titanium dioxide particle 21c is controlled in this condition to increase its dispersibility. Next, a thickener, a dispersant or the like is uniformly admixed with an aqueous solution in which the titanium dioxide particle is dispersed to thereby prepare a uniform acidic aqueous paste. As the thickener, glycols such as a polyethylene glycol or the like can be used. As the dispersant, acetylacetone or Triton-X100 (an alkylphenoxypolyethylene glycol type nonionic surfactant) can be used. The polyethylene glycol is added as the thickener because the viscosity of the acidic aqueous paste can be increased to form the thick film, and the polyethylene glycol is vaporized during the heating of the acidic aqueous paste and thus a communicating connection pore penetrating from the surface to the back surface of the porous film 21b containing the titanium dioxide particle 21c is formed. In addition, the adhesive strength of the porous film 21b to the first electrically-conductive film 21a can be increased. When a surfactant such as Triton-X100 or the like is used as the dispersant, there is an advantage that a residual component does not remain after heating

The method for forming the porous film 21b is as follows: When a glass plate is used as the first base material 11, the porous film 21b is formed on the first electrically-conductive film 21a by coating the above-mentioned acidic aqueous paste on the first electrically-conductive film 21a of the first base material 11. In this case, the coating can be carried out by a doctor-blade method, a squeegee method, a spin coat method, a screen printing method or the like. After drying, the coated base material is placed into an electric furnace and burned at 300 to 600° C. for 30 to 90 minutes in an atmosphere. The porous film 21b constitutes a working electrode 21 together with the first electrically-conductive film 21a and the dye 21d described hereinafter. The burning temperature is limited within the range from 300 to 600° C. because if the temperature is less than 300° C., an organic additive which cannot be completely burned may remain and prevent the absorption of the dye, and the high photovoltaic property cannot be obtained since the titanium dioxide particle itself is not sufficiently burned. If the temperature is more than 600° C., the first base material 11 is softened and causes difficulty in making a working electrode 21. The burning time is limited within the range from 30 to 90 minutes because if the time is less than 30 minutes, the sintering may be inferior, and if the time is more than 90 minutes, the specific surface area may be decreased since the growth of the particle is too advanced. Moreover, when the flexible plastic film (for example, a polyethylene terephthalate film) is used as the first base material, the porous film is formed by coating the acidic aqueous paste on the first electrically-electrically-conductive film of the first base material, carrying out a press forming if necessary, radiate microwaves to form the porous film on the first electrically-conductive film 21a, wherein the coating is carried out by a squeegee (applicator) method, a screen printing method, an electrodeposition method, a spray method, DJP (a direct jet printing) method or the like.

The first base material 11, in which the porous film 21b is made on the first electrically-conductive film 21a, is then dipped in a dye solution to fix the dye 21d to the porous film 21b by absorbing it. As the dye 21d, a ruthenium complex can be preferably used, more particularly, an organic dye exhibiting a photoelectric effect, such as a methine dye, a xanthene dye, a porphyrin dye, a phthalocyanine dye, an azo dye, a coumarin dye or the like can be preferably used, and a mixture of one or more kinds selected from the group consisting of these dyes can be also preferably used as the photovoltaic material. When a ruthenium complex is used as the dye 21d, the ruthenium complex is dissolved with a single solvent, such as acetonitrile, t-BuOH, ethanol or the like, or a mixed solvent of these solvents to prepare the dye solution, and the concentration of the dye solution is prepared to 5×10⁻⁴ mol. The dipping of the first base material 11 in the dye solution is carried out at room temperature for about 20 hours in general. At this time, although the dipping time of the first base material 11 in the dye solution is about 20 hours, the dipping time can be reduced to as little as about 5 minutes by heating and carbonizing the dye solution at near the boiling point. With respect to the film thickness of the titanium dioxide particle, the damage to the electrode or the like, it can be prepared so as to maximize the amount of the absorbed dye by using a suitable operation temperature in each case. Furthermore, the surface of the porous film 21b with the dye absorbed thereon is washed and dried. This allows the manufacture of the photovoltaic device 10

The photovoltaic device 10 produced by this way, because of the high amount of the dye absorbed per unit volume and unit area, exhibits a high short circuit current density of the dye-sentitized solar cell 80 and thus the photon-to-electron conversion efficiency is high.

The method for manufacturing the dye-sensitized solar cell 80 using the photovoltaic device 10 is as follows:

A counter electrode 22 is made by forming a second electrically-conductive film 22a on a second base material 12. The second electrically-conductive film 22a is formed on one side, both sides, or the entire surface of the second base material 12 by the vapor deposition method, the sputtering method, the ion plating method, hydrolysis or the like. As the second base material, a glass plate or a flexible plastic film can be preferably used. As the second electrically-conductive film 22a, a platinum foil, a film in which fluorine is doped in tin oxide (FTO), or a film in which a small amount of tin oxide is mixed with indium oxide (ITO film) can be preferably used. Additionally, an electrolyte solution 13 is stored between the working electrode 21 and the counter electrode 22, wherein the working electrode 21 of the first base material 11 and the counter electrode 22 of the second base material 12 are separated by a predetermined interval. The electrolyte solution 13 is prepared by mixing a support electrolyte, a redox pair, and a single solvent or a mixed solvent of alcohols, e.g., ethanol, t-butanol, and the like or nitrites, e.g., acetonitrile, methoxyacetonitrile, 3-methoxypropionitrile and the like. The support electrolyte comprises cations such as a lithium ion or the like and anions such as a chlorine ion or the like and the redox pair is an iodine-iodine compound, a bromine-bromine compound or the like, which exist in the support electrolyte. In addition, in order to keep the space between the working electrode 21 of the first base material 11 and the counter electrode 22 of the second base material 12 within the predetermined value, a spacer made with a resin film having a thickness of 10 to 30 μm (which is not shown in the drawings) is placed between the working electrode 21 and the counter electrode 22. Further, in order to prevent leakage of the electrolyte solution 13, an electric insulation adhesive such as an epoxy resin or the like is coated on the periphery areas between the working electrode 21 and the counter electrode 22, and cured. Because of the high amount of dye absorbed per unit volume and unit area, a dye-sensitized solar cell 80 made in this way exhibits a high short circuit current density resulting in a high photon-to-electron conversion efficiency.

### EXAMPLES

### Example 1

A titanium dioxide particle was made by mixing a raw material gas, introducing the mixed raw material gas into a burner 53 of a flame hydrolysis apparatus of FIG. 2, and flame-hydrolyzing, wherein the raw material gas was mixed so as to have a flow rate of titanium tetrachloride gas of 110 kg/hour, a flow rate of hydrogen gas of 30 Nm³/hour, and a flow rate of air of 600 Nm³/hour. The properties of the titanium dioxide particle obtained are shown in Table 1. In addition, the theoretical burning temperature of the flame in the flame hydrolysis was 510° C.

### Example 2

A titanium dioxide particle was made by mixing a raw material gas, introducing the mixed raw material gas into a burner 53 of a flame hydrolysis apparatus of FIG. 2 and flame-hydrolyzing it, wherein the raw material gas was mixed so as to have a flow rate of titanium tetrachloride gas of 100 kg/hour, a flow rate of hydrogen gas of 27 Nm³/hour, and a flow rate of air of 660 Nm³/hour. The properties of the titanium dioxide particle obtained are shown in Table 1. In addition, the theoretical burning temperature of the flame in the flame hydrolysis was 450° C.

### Comparison Example 1

A titanium dioxide particle was made by mixing a raw material gas, introducing the mixed raw material gas into a burner 53 of a flame hydrolysis apparatus of FIG. 2, and flame-hydrolyzing it, wherein the raw material gas was mixed so as to have a flow rate of titanium tetrachloride gas of 120 kg/hour, a flow rate of hydrogen gas of 33 Nm³/hour, and a flow rate of air of 500 Nm³/hour. The properties of the titanium dioxide particle obtained are shown in Table 1. In addition, the theoretical burning temperature of the flame in the flame hydrolysis was 720° C.

### Comparison Test 1 and Evaluation

The containing ratio (wt %) of crystalline anatase, the BET specific surface area (m²/g), and oil absorption (ml/100 g) of the titanium dioxide particles of Example 1, Example 2 and Comparison example 1 were measured. These results are shown in Table 1 together with each flow rate of titanium tetrachloride gas, hydrogen gas and air, and each theoretical burning temperature of the flame. In addition, the containing ratio of the anatase crystalline contained in the titanium dioxide particle was measured from the results of powder X-ray analysis. Moreover, the BET specific surface area of the titanium dioxide particle was obtained by absorbing gas molecules (nitrogen molecules) having a publicly known occupation area on the surface of the titanium dioxide particle, and measuring the absorbed amount of the gas molecules. Further, the oil absorption was measured by the method according to JIS K5101. More particularly, an oil absorption A (ml/100 g) was determined, by putting 2.00 g of the titanium dioxide particle on a glass plate, dropping a boiled linseed oil little by little from a micro view onto the glass plate, mixing it well with a regular metal turner, finishing the mixing when the mixture of the oil and the titanium dioxide particle becomes putty-like and moldable, measuring the amount of the linseed oil at this time, and calculating the oil absorption A by using the following formula (1).
A=(V/2.00)×100 (1)

TABLE 1

| | Flow Rate of Raw Material | | | Theoretical | Containing | BET | |
|---|---|---|---|---|---|---|---|
| | Mixed Gas | | | Burning | Ratio of | Specific | |
| | Titanium | | | Temperature | Crystalline | Surface | Oil |
| | Tetrachloride | Hydrogen | Air | of Flame | Anatase | Area | Absorption |
| | (kg/h) | (Nm³/h) | (Nm3/h) | (° C.) | (wt %) | (m²/g) | (ml/100 g) |
| Example 1 | 110 | 30 | 600 | 510 | 88 | 73 | 71 |
| Example 2 | 100 | 27 | 660 | 450 | 87 | 86 | 78 |
| Comparison | 120 | 33 | 500 | 720 | 81 | 51 | 65 |
| example 1 | | | | | | | |

Clearly from Table 1, although the BET specific surface area of Comparison example 1 was small, that is, 51 m²/g, the BET specific surface areas of Examples 1 and 2 were large, that is, 73 m²/g and 86 m²/g. Moreover, although there was low oil absorption of Comparison example 1, that is, 65 ml/100 g, there was high oil absorption in Examples 1 and 2, that is, 71 ml/100 g and 78 ml/100 g. Therefore, it was found out that the viscosity of the acidic aqueous solution was suitable.

### Comparison Test 2 and Evaluation

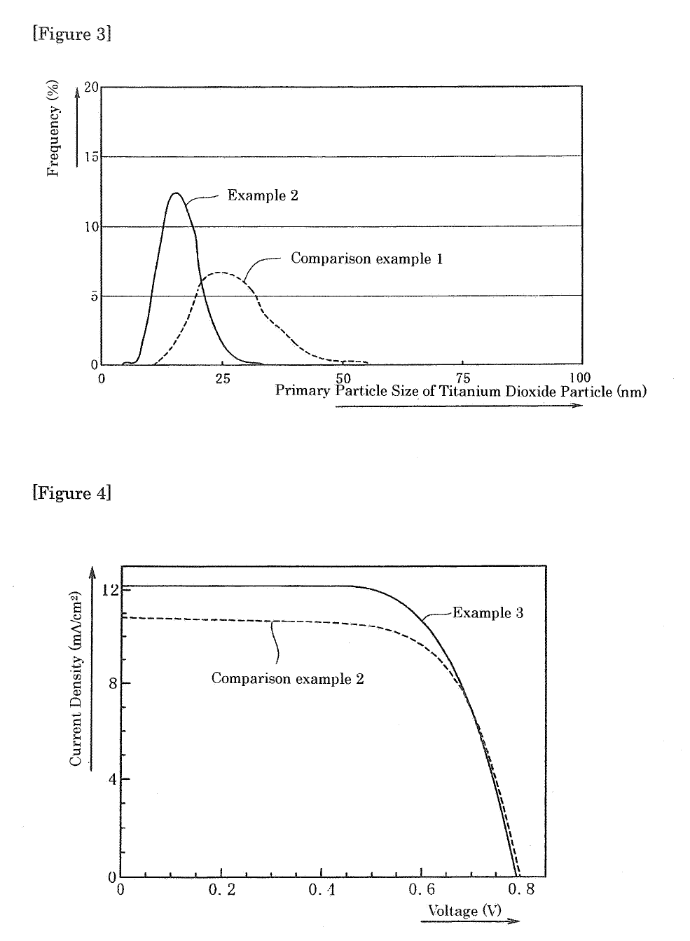

The particle size distribution of a powder comprising the titanium dioxide particles of Example 2 and Comparison example 1 was measured. The measurement was carried out by photographing the powder comprising the titanium dioxide particle by an electron microscope, counting each number of particles from the photography, and measuring the particle size distribution of the primary particle. These results are shown in FIG. 3.

Clearly from FIG. 3, it was found that the particle size distribution curve of the powder comprising the titanium dioxide particle of Example 2 was sharper than that of Comparison example 1, and the primary particle of the titanium dioxide particle of Example 2 was uniform compared to that of Comparison example 1.

### Example 3

First, 2.1 g of the powder comprising the titanium dioxide particle of Example 2 was mixed with 4.9 g of nitric acid water (pH: 0.7) to prepare the acidic aqueous solution in which the titanium dioxide particle was dispersed. Next, 0.21 g of acetylacetone and 0.105 g of polyethylene glycol (an average molecular weight: 500,000) were mixed with the acidic aqueous solution, in which the titanium dioxide particle was dispersed, to prepare the acidic aqueous paste. This acidic aqueous paste was coated on the first electrically-conductive film 21a on the first base material 11 in the shape of a square where the length and width were 5 mm respectively. The first base material 11 having the first electrically-conductive film 21a was a glass plate made by Nippon Sheet Glass Co. Ltd., wherein the first electrically-conductive film 21a, i.e., the film where fluorine was doped to tin oxide, was vapor-deposited on the one side of the glass plate, and the surface resistivity of the first electrically-conductive film 21a was 5 to 15 Ω/□. Next, the porous film 21b was made by heating the first base material 11 having the first electrically-conductive film 21a, which was coated with the acidic aqueous paste, in an electric furnace, and keeping it at 500° C. under an atmosphere for 30 minutes to calcine it to produce a porous film 21b containing the titanium dioxide particle 21c on the first electrically-conductive film 21a. Further, Ruthenium535-bisTBA (made by Solaronix Company) was used as the dye 21d, which was dissolved with the mixed solvent of acetonitrile and t-BuOH, to make the dye solution having a dye concentration being adjusted to 5×10⁻⁴ mol. The dye 21d was absorbed to the porous film 21b by dipping the first base material 11 in this dye solution for 12 hours and settled. The surface of the porous film 21b absorbed with the dye 21d was washed with acetonitrile and dried to produce a photovoltaic device 10 with a working electrode 21 consisting of the first electrically-conductive film 21a, porous film 21b and the dye 21d, formed on the first base material 11.

The counter electrode 22 was made by vaporizing the second electrically-conductive film 22a of platinum foil having a thickness of 0.1 μm on one side of the second base material 12 comprising the glass plate. As the electrolyte solution 13, a methoxyacetonitrile solution was used which was prepared by mixing 0.1 mol of lithium iodide, 0.05 mol of iodine, 0.5 mol of 4-t-butyl pyridine and 0.6 mol of 1-propyl-2,3-dimethylimidazolium iodide. Next, a resin-film spacer made with a himilan film (made by Du Pont-Mitsui Polychemicals Co. Ltd.) having a thickness of 20 μm (which is not shown in the drawings) was placed between the working electrode 21 and the counter electrode 22 and the electrolyte solution 13 was enclosed between the electrodes 21 and 22. Then, the dye-sentitized solar cell 80 was made and shown as Example 3.

### Comparison Example 2

The dye-sensitized solar cell was made like Example 3 excepting that the acidic aqueous paste was prepared by mixing 2.1 g of the powder comprising the titanium dioxide particle of Comparison example 1 with 4.9 g of the nitric acid water (pH:0.7) to prepare the acidic aqueous solution, and mixing 0.21 g of acetylacetone and 0.105 g of polyethylene glycol (the average molecular weight: 500,000) with this acidic aqueous solution, in which the titanium dioxide particle was dispersed. The dye-sensitized solar cell was shown as Comparison example 2.

### Comparison Test 3 and Evaluation

The I-V curve characteristics of the dye-sensitized solar cells of Example 3 and Comparison example 2 were measured respectively by using a 300 W solar simulator (made by Oriel Company) as a light source, irradiating light so as to have the irradiation light amount of 100 mW/cm² [AM (Air/Mass) 1.5 G], and using a potentiator (HSV-100F made by Hokuto-denko Co. Ltd.). These results were shown in FIG. 4.

Clearly from FIG. 4, although the short circuit current density of the dye-sensitized solar cell of Comparison example 2 was low, that is, 10.9 mA/cm², the short circuit current density of the dye-sensitized solar cell of Example 3 was high, that is, 12.2 mA/cm².

Moreover, the photon-to-electron conversion efficiency η (%) of the dye-sensitized solar cells of Example 3 and Comparison example 2 were measured. The photon-to-electron conversion efficiency η (%) was calculated from the following formula (2) using Voc (an open-circuit voltage value), Isc (a short circuit current value), ff (a filter factor value), L (irradiation light amount: mW/cm²), and S (an area of the porous film: cm²).
η=(Voc×|sc×ff×100)/(L×S) (2)

As the result, although the photon-to-electron conversion efficiency of Comparison example 2 was low, that is, 5.56%, the photon-to-electron conversion efficiency of Example 3 was high, that is, 6.21%.

1-5. (canceled)

6. A titanium dioxide particle having 70 to 95% by weight crystalline anatase, a BET specific surface area from 65 to 120 m²/g, and an oil absorption from 70 to 90 ml/100 g measured by the method according to JIS K5101.

7. The titanium dioxide particle of claim 1 having from 75 to 90% by weight crystalline anatase.

8. The titanium dioxide particle of claim 1 wherein the BET specific surface area is from 70 to 100 m²/g.

9. The titanium dioxide particle of claim 1 wherein the oil absorption is from 70 to 85 ml/100 g.

10. A photovoltaic device comprising a light-transmittable base material (11) and a porous film (21b) formed on the base material and having a dye (21d) absorbed thereon,
wherein said porous film (21b) having said dye (21d) absorbed thereon contains titanium dioxide particles (21c) having 70 to 95% by weight crystalline anatase, a BET specific surface area of 65 to 120 m²/g, and an oil absorption of 70 to 90 ml/100 g measured by the method according to JIS K5101.

11. The photovoltaic device according to claim 5, wherein the base material (11) is a glass plate or a flexible plastic film.

12. The photovoltaic device according to claim 5 wherein the titanium dioxide particle titanium dioxide particle contains from 75 to 90% by weight crystalline anatase.

13. The photovoltaic device according to claim 5 wherein the titanium dioxide particle has a BET specific surface area from 70 to 100 m²/g.

14. The photovoltaic device according to claim 5 wherein the titanium dioxide particle has and oil absorption from 70 to 85 ml/100 g.

15. The photoelectric device of claim 5 wherein the dye exhibits a photoelectric effect.

16. The photovoltaic device of claim 5 wherein the dye is selected from the group consisting of a methine dye, a xanthene dye, a porphyrin dye, a phthalocyanine dye, an azo dye, a coumarin dye and mixtures thereof.

17. The photovoltaic device of claim 5 wherein the dye is a ruthenium complex.

18. A method for manufacturing a titanium dioxide particle by flame-hydrolyzing titanium tetrachloride in a hydrogen burning flame,
wherein the theoretical burning temperature of said flame is set within the range from 400° to 700°.

19. The method of claim wherein the theorectical burning temperature is from 450 to 600°

20. A dye-sensitized solar cell having the photovoltaic device of claim 5.

21. A dye sensitized solar cell having the photovoltaic device of claim 6.

22. A dye sensitized solar cell having the photovoltaic device of claim 7.

23. A dye sensitized solar cell having the photovoltaic device of claim 8.

24. A dye sensitized solar cell having the photovoltaic device of claim 9.

25. A dye sensitized solar cell having the photovoltaic device of claim 10.
